(19) United States
(12) Patent Application Publication
(10) Pub. No.: US 2025/0005236 A1
(43) Pub. Date: Jan. 2, 2025

(54) DEVICE AND METHOD FOR ACCELERATING PHYSICS-BASED SIMULATIONS USING ARTIFICIAL INTELLIGENCE

(71) Applicant: Advanced Micro Devices, Inc., Santa Clars, CA (US)

(72) Inventors: Laurent S. White, Austin, TX (US); Darian Osahar Nwankwo, Ithaca, NY (US); Gurpreet Singh Hora, New York, NY (US)

(73) Assignee: Advanced Micro Devices, Inc., Santa Clara, CA (US)

(21) Appl. No.: 18/344,544

(22) Filed: Jun. 29, 2023

(51) Int. Cl. G06F 30/27

(52) U.S. Cl. CPC G06F 30/27

(57) ABSTRACT

Method and devices are provided for performing a physics-based simulation. A processing devices comprises memory and a processor. The processor is configured to perform a physics-based simulation by executing a portion of the physics-based simulation, training a neural network model based on results from executing the first portion of the physics-based simulation, performing inference processing based on the results of the training of the neural network model and providing a prediction, based on the inference processing, as an input back to the physics-based simulation.

### BACKGROUND

Physics-based simulations have been used for decades to make predictions about physical processes and make decisions based on the predictions. For example, physics-based simulations are used for numerical weather forecasting and computational fluid dynamics for aircraft design. These physics-based simulations have benefited from years of improvement in computing algorithms (e.g., algorithms implemented via software) and hardware, making them a standard tool in many scientific fields, alongside lab and field experiments.

### BRIEF DESCRIPTION OF THE DRAWINGS

A more detailed understanding can be had from the following description, given by way of example in conjunction with the accompanying drawings wherein:

FIG. 1 is a block diagram of an example computing device in which one or more features of the disclosure can be implemented;

FIG. 2 is a block diagram of the device, illustrating additional details related to execution of processing tasks on an accelerated processing device, according to an example;

FIG. 3 is a flow diagram illustrating an example method 300 of accelerating a physics-based simulation according to features of the disclosure; and

FIG. 4 illustrates a comparison between the time used to perform the physics-based simulation without using a neural network and the time used to perform the physics-based simulation by combining the physics-based simulation with a neural network, according to an example.

### DETAILED DESCRIPTION

While physics-based simulations are very useful for making predictions and decisions about physical processes, physics-based simulations often require very large supercomputers with hundreds to thousands of compute nodes, and millions of compute cores. For example, the power required to operate the largest supercomputers can be larger than 10 MW.

While physics-based simulations can be highly accurate, they are also expensive. For example, the grid-based or mesh-based numerical methods used in physics-based simulations require a large number of floating-point operations to be performed and sometimes results in weeks of computations on the largest computers to reach a final state of the simulation. The high cost of physics-based simulations often prevents their use for making predictions and decisions for various physical processes (e.g., designing a new machine, designing new materials or making societal decisions).

In addition, physics-based simulations result in inefficient use of hardware. For example, a recent slowdown in single-core performance improvement has resulted in physics-based simulations being scaled out to many cores, requiring data communication across many nodes. More time is often spent moving data (e.g., between memory and a processor core, or between nodes via a network) than performing work (e.g., performing computations using the data). Even at a node level, grid-based and mesh-based computations are typically memory-bandwidth-limited (i.e., a low ratio of computations are performed per unit of data moved from memory to registers).

Artificial intelligence is a technology which causes a machine (e.g., computer) to mimic or simulate human intelligence. Machine learning, a subfield of artificial intelligence, enables a machine to learn and improve from experience (e.g., training) to solve complex problems.

“Machine learning networks” are used herein interchangeably with the terms “neural networks,” “machine learning neural networks,” “deep learning neural networks,” and “machine learning models.”

Machine learning neural networks are widely used in a variety of technologies (e.g., image classification) to make predictions or decisions to perform particular tasks (e.g., whether an image includes a certain object). The neural networks typically include multiple layers. At each layer, a filter is applied to the previous layer, and the results of each layer are known as activations or feature maps. The first and last layers in a neural network are known as the input and output layers, respectively, and the layers in between the first and last layers are known as hidden layers. Machine learning models are trained in order to make predictions or decisions to perform a particular task (e.g., whether an image includes a certain object). During training, a model is exposed to different data. At each hidden layer, the model learns essential feature maps from the data. At the output layer, the model makes a prediction and receives feedback regarding the accuracy of its prediction to update itself.

Features of the present disclosure include devices and methods for accelerating physics-based simulations by performing portions of the simulations using machine learning networks. Portions of the physics-based simulations are replaced with a machine learning neural network model and switched back, from the neural network model, to the physics-based simulations (e.g., a neural network is trained based on the results of a portion of the physics-based simulation, inference processing is performed based on the trained neural network model and a prediction resulting from the inference processing is provided, as an initial condition, back to the physics-based simulation).

The machine learning networks are used as efficient approximations of the physics-based simulations to make predictions using fewer floating-point operations than physics-based simulations. The approximation quality of a simulation is tuned to a target accuracy for a specific simulation (e.g., a specific use case). Accordingly, the specific application (use case) can be accelerated by using the machine learning networks for portions of the physics-based simulations while maintaining a target accuracy.

Machine learning networks also utilize the computing hardware (e.g., memory and registers) more efficiently than physics-based simulations because machine learning networks have a smaller footprint (i.e., smaller model size) than physics-based simulations and have a higher arithmetic intensity than physics-based simulations. That is, the ratio of computations performed per unit of data moved from memory to registers is higher when using machine learning networks than the ratio of computations to data movement when using physics-based simulations.

A processing device for performing a physics-based simulation is provided which includes memory and a processor. The processor is configured to perform the physics-based simulation by executing a portion of the physics-based simulation, training a neural network model based on results from executing the first portion of the physics-based simulation, performing inference processing based on the results of the training of the neural network model and providing a prediction, based on the inference processing, as an input back to the physics-based simulation.

A method for performing a physics-based simulation is provided which comprises executing a portion of the physics-based simulation, training a neural network model based on results from executing the first portion of the physics-based simulation, performing inference processing based on the results of the training of the neural network model and providing a prediction, based on the inference processing, as an input back to the physics-based simulation.

A method of performing a physics-based simulation is provided which comprises executing a first portion of the physics-based simulation, training a neural network based on the results of the first portion of the physics-based simulation to generate a trained neural network model, executing a second portion of the physics-based simulation during a period of time in which the neural network model is trained, performing inference processing based on the results of the trained neural network model and providing the last prediction of the inference processing to a third portion of the physics-based simulation when execution of the inference processing completes. One or more predictions, regarding physical processes, are generated from the results of the physics-based simulation.

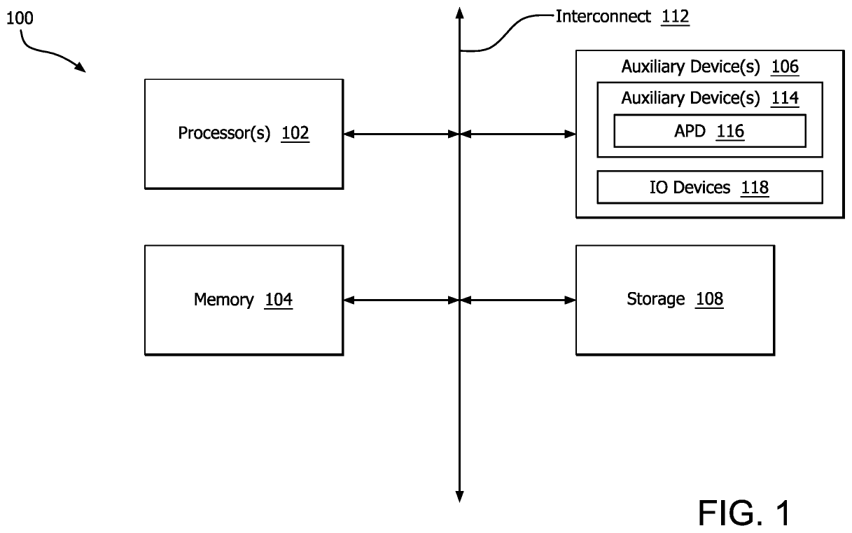

FIG. 1 is a block diagram of an example computing device 100 in which one or more features of the disclosure can be implemented. In various examples, the computing device 100 is one of, but is not limited to, for example, a computer, a gaming device, a handheld device, a set-top box, a television, a mobile phone, a tablet computer, or other computing device. The device 100 includes, without limitation, one or more processors 102, a memory 104, one or more auxiliary devices 106 and storage 108. An interconnect 112, which can be a bus, a combination of buses, and/or any other communication component, communicatively links the processor(s) 102, the memory 104, the auxiliary device(s) 106 and the storage 108.

In various alternatives, the processor(s) 102 include a central processing unit (CPU), a graphics processing unit (GPU), a CPU and GPU located on the same die, or one or more processor cores, wherein each processor core can be a CPU, a GPU, or a neural processor. In various alternatives, at least part of the memory 104 is located on the same die as one or more of the processor(s) 102, such as on the same chip or in an interposer arrangement, and/or at least part of the memory 104 is located separately from the processor(s) 102. The memory 104 includes a volatile or non-volatile memory, for example, random access memory (RAM), dynamic RAM, or a cache.

The storage 108 includes a fixed or removable storage, for example, without limitation, a hard disk drive, a solid state drive, an optical disk, or a flash drive. The auxiliary device(s) 106 include, without limitation, one or more auxiliary processors 114, and/or one or more input/output (“IO”) devices. The auxiliary processor(s) 114 include, without limitation, a processing unit capable of executing instructions, such as a central processing unit, graphics processing unit, parallel processing unit capable of performing compute shader operations in a single-instruction-multiple-data form, multimedia accelerators such as video encoding or decoding accelerators, or any other processor. Any auxiliary processor 114 is implementable as a programmable processor that executes instructions, a fixed function processor that processes data according to fixed hardware circuitry, a combination thereof, or any other type of processor. In some examples, the auxiliary processor(s) 114 include an accelerated processing device (“APD”) 116. In addition, although processor(s) 102 and APD 116 are shown separately in FIG. 1, in some examples, processor(s) 102 and APD 116 may be on the same chip.

The one or more IO devices 118 include one or more input devices, such as a keyboard, a keypad, a touch screen, a touch pad, a detector, a microphone, an accelerometer, a gyroscope, a biometric scanner, or a network connection (e.g., a wireless local area network card for transmission and/or reception of wireless IEEE 802 signals), and/or one or more output devices such as a display, a speaker, a printer, a haptic feedback device, one or more lights, an antenna, or a network connection (e.g., a wireless local area network card for transmission and/or reception of wireless IEEE 802 signals).

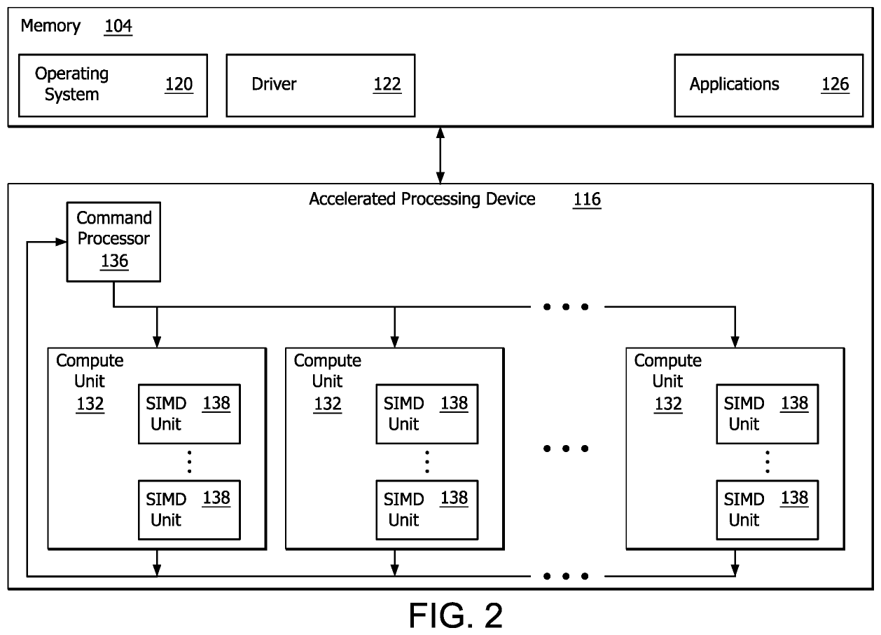

FIG. 2 is a block diagram of the device, illustrating additional details related to execution of processing tasks on the APD 116, according to an example. The processor 102 maintains, in system memory 104, one or more control logic modules for execution by the processor(s) 102. The control logic modules include an operating system 120, a driver 122, and applications 126, and may optionally include other modules not shown. These control logic modules control various aspects of the operation of the processor(s) 102 and the APD 116. For example, the operating system 120 directly communicates with hardware and provides an interface to the hardware for other software executing on the processor(s) 102. The driver 122 controls operation of the APD 116 by, for example, providing an application programming interface (“API”) to software (e.g., applications 126) executing on the processor(s) 102 to access various functionality of the APD 116. The driver 122 also includes a just-in-time compiler that compiles shader code into shader programs for execution by processing components (such as the SIMD units 138 discussed in further detail below) of the APD 116.

The APD 116 executes commands and programs for selected functions, such as graphics operations and non-graphics operations, which may be suited for parallel processing. The APD 116 can be used for executing graphics pipeline operations such as pixel operations, geometric computations, and rendering an image to a display device (e.g., one of the IO devices 118) based on commands received from the processor(s) 102. The APD 116 also executes compute processing operations that are not directly related to graphics operations, such as operations related to video, physics simulations, computational fluid dynamics, or other tasks, based on commands received from the processor 102 or that are not part of the “normal” information flow of a graphics processing pipeline, or that are completely unrelated to graphics operations (sometimes referred to as “GPGPU” or “general purpose graphics processing unit”).

The APD 116 includes compute units 132 (which may collectively be referred to herein as “programmable processing units”) that include one or more SIMD units 138 that are configured to perform operations in a parallel manner according to a SIMD paradigm. The SIMD paradigm is one in which multiple processing elements share a single program control flow unit and program counter and thus execute the same program but are able to execute that program with different data. In one example, each SIMD unit 138 includes sixteen lanes, where each lane executes the same instruction at the same time as the other lanes in the SIMD unit 138 but can execute that instruction with different data. Lanes can be switched off with predication if not all lanes need to execute a given instruction. Predication can also be used to execute programs with divergent control flow. More specifically, for programs with conditional branches or other instructions where control flow is based on calculations performed by individual lanes, predication of lanes corresponding to control flow paths not currently being executed, and serial execution of different control flow paths, allows for arbitrary control flow to be followed.

The basic unit of execution in compute units 132 is a work-item. Each work-item represents a single instantiation of a shader program that is to be executed in parallel in a particular lane of a wavefront. Work-items can be executed simultaneously as a “wavefront” on a single SIMD unit 138. Multiple wavefronts may be included in a “work group,” which includes a collection of work-items designated to execute the same program. A work group can be executed by executing each of the wavefronts that make up the work group. The wavefronts may be executed sequentially on a single SIMD unit 138 or partially or fully in parallel on different SIMD units 138. Wavefronts can be thought of as instances of parallel execution of a shader program, where each wavefront includes multiple work-items that execute simultaneously on a single SIMD unit 138 in line with the SIMD paradigm (e.g., one instruction control unit executing the same stream of instructions with multiple data). A command processor 137 is present in the compute units 132 and launches wavefronts based on work (e.g., execution tasks) that is waiting to be completed. A scheduler 136 is configured to perform operations related to scheduling various wavefronts on different compute units 132 and SIMD units 138.

The parallelism afforded by the compute units 132 is suitable for graphics related operations such as pixel value calculations, vertex transformations, tessellation, geometry shading operations, and other graphics operations. A graphics processing pipeline 134 which accepts graphics processing commands from the processor(s) 102 thus provides computation tasks to the compute units 132 for execution in parallel.

The compute units 132 are also used to perform computation tasks not related to graphics or not performed as part of the “normal” operation of a graphics processing pipeline 134 (e.g., custom operations performed to supplement processing performed for operation of the graphics processing pipeline 134). An application 126 or other software executing on the processor(s) 102 transmits programs (often referred to as “compute shader programs,” which may be compiled by the driver 122) that define such computation tasks to the APD 116 for execution. Although the APD 116 is illustrated with a graphics processing pipeline 134, the teachings of the present disclosure are also applicable for an APD 116 without a graphics processing pipeline 134.

The APD 116 is configured to perform various functions to accelerate physics-based simulations by performing portions of the physics-based simulations using machine learning networks while maintaining a target accuracy and utilize computing hardware more efficiently. For example, as described in more detail herein, the APD 116 is configured to, without limitation, perform portions of the physics-based simulations, train (or retrain) neural network models based on results of the portions of the physics-based simulation, perform inference processing to make predictions based on the results of the trained neural network models and provide the predictions back to the portions of the physics-based simulations.

The APD 116 is also configured to make various decisions to accelerate physics-based simulations, such as decisions of whether or not to train a neural network or retrain a neural network, whether to retrain a neural network model based on new simulation data, or whether to use a previously trained neural network model as an initial estimation in a new training phase based on new data.

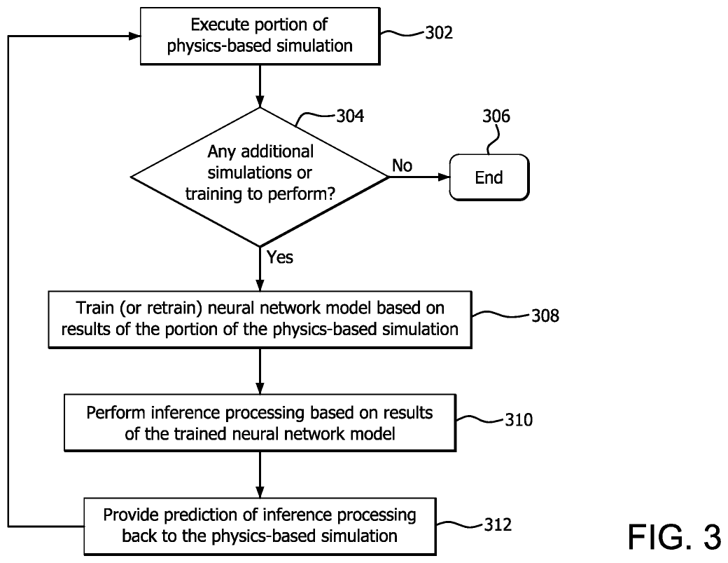

FIG. 3 is a flow diagram illustrating an example method 300 of accelerating a physics-based simulation according to features of the disclosure. Each of the steps shown in the method 300 at FIG. 3 are performed by an accelerated processor (e.g., APD 116 shown in FIG. 2).

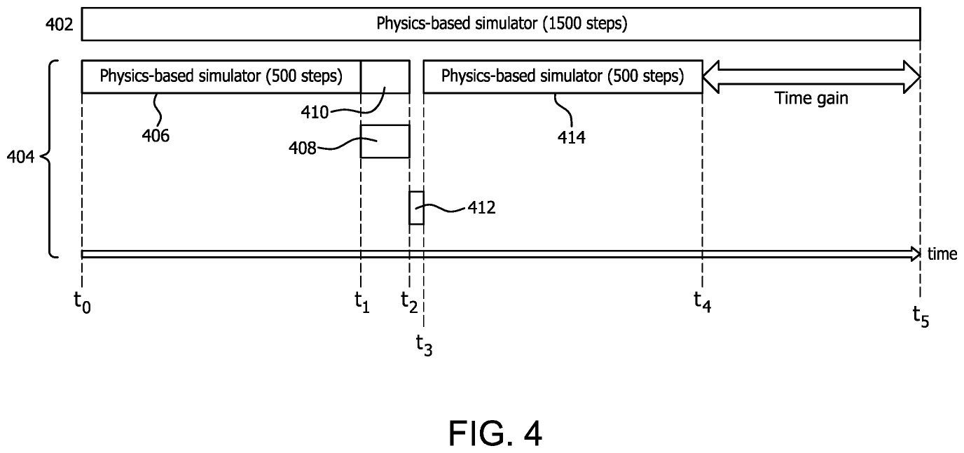

The example method 300 is described using the timing diagram shown in FIG. 4. The top portion of FIG. 4 illustrates a baseline workflow 402 of performing the physics-based simulation without using a neural network and the bottom portion of FIG. 4 illustrates a hybrid workflow 404 of performing the physics-based simulation by combining the physics-based simulation with a neural network according to features of the present disclosure. FIG. 4 illustrates a comparison between the time used to perform the physics-based simulation without using a neural network (i.e., the baseline workflow 402 shown at the top of FIG. 4) and the time used to perform the physics-based simulation according to the hybrid workflow 404.

As shown in FIG. 4, both the baseline workflow 402 and the hybrid workflow 404 are performed using 1500 steps. The total number of steps (1500) shown in FIG. 4 is merely an example. Features of the present disclosure can include any number of steps, different than the 1500 steps shown in FIG. 4, to perform the hybrid workflow 404. In addition, in the example shown in FIG. 4 the hybrid workflow 404 includes performing different portions of the physics-based simulation each comprising 500 steps as well as an inference phase portion comprising 500 steps. However, features of the present disclosure can include performing each portion of the hybrid workflow 404 using any number of steps, different than the 500 steps shown in FIG. 4.

As shown at block 302, the method 300 includes performing (e.g., executing by APD 116) a portion of the physics-based simulation. The portion of the physics-based simulation is performed (e.g., by APD 116) for a number of steps. For example, as shown in FIG. 4, a first portion of the physics-based simulation 406 is performed for 500 steps, beginning at time to and ending at time t₁. During the performing of any portion of the physics-based simulation (e.g., the first portion of the physics-based simulation 406), the simulation results in space and time, or part of the simulation results, are saved in memory. For example, in some cases, a subsample in space and time is saved in memory. Additionally, or alternatively, some state variables can be saved to memory while other state variables are not saved to memory.

As shown at decision block 304, the method 300 includes determining whether there are any additional portions of the physics-based simulation or any additional training to perform. In response to there not being any additional portions of the physics-based simulation to be performed and there not being any additional training of a neural network to be performed (as described in more detail below) (No decision), the method ends at block 306.

However, in response to at least one of an additional portion of the physics-based simulation determined to be performed and additional training of a neural network determined to be performed (Yes decision), the method proceeds to block 308 to train (or retrain as described in more detail below) a neural network based on results of the portion of the physics-based simulation. For example, when the accelerated processor (e.g., APD 116) finishes performing a number of steps for first portion of the physics-based simulation 406 at time t₁, and there are still additional portions of the physics-based simulation (i.e., a second portion 410 and third portion 414) to be performed, a neural network model 408 is trained (e.g., by APD 116), at block 308, based on the results of the first portion of the physics-based simulation 406.

A portion of a physics-based simulation ends (and the decision is made at block 304) for example, based on any of a number of different criteria. For example, as shown in FIG. 4, the first portion of the physics-based simulation 406 ends, at time t₁, after completing a number of steps (e.g., 500 steps). Alternatively, a portion of a physics-based simulation end (and a next portion begins), for example, based on other criteria which includes, but is not limited to, a predetermined amount of time expires from when the portion of the physics-based simulation begins, or based on a determination that the results of a portion of the physics-based simulation are sufficient for training the neural network).

As shown in FIG. 4, training of a neural network model 408 is executed (e.g., by APD 116), beginning at time t₁ and ending at time t₂. Experimental data (e.g., laboratory data or field data) can also be used to train a neural network model.

As further shown in FIG. 4, while the neural network model 408 is trained between time t₁ and time t₂, a second portion of the physics-based simulation 410 also executes between time t₁ and time t₂. The additional data generated by second portion of the physics-based simulation 410 can be provided, as input in real-time, to the neural network model 408 during training. Alternatively, the additional data generated by second portion of the physics-based simulation 410 can be used to validate the trained neural network model 408, i.e., the first 500 steps generates the training data set and the additional data forms the validation set.

As shown at block 310, the method 300 includes performing inference processing (i.e., an inference phase to make one or more predictions) based on the results of the trained neural network model. For example, as shown in FIG. 4, based on the results of the training of the neural network model 408, inference processing (i.e., inference phase 412) is performed between time t₂ and time t₃. In the example shown in FIG. 4, inference phase 412 is also performed for the same number of steps (500 steps) as the first portion of the physics-based simulation 410. Accordingly, as illustrated by the smaller time interval between time t₂ and time t₃, (compared to the larger time interval between time to and time t₁), the inference phase 412 (based on the results of the trained neural network) is performed much faster than the physics-based simulation for the same number of steps.

Inference phase 412 continues executing until it reaches a number of steps (e.g., specified by a user via a user input), the prediction no longer satisfies a physics relationship (e.g., as defined by the user input), or a prediction uncertainty is equal to or greater than a threshold prediction uncertainty (e.g., as specified by the user input).

As shown at block 312, the method 300 includes providing the prediction (e.g., the last prediction) of the inference processing back to the physics-based simulation when execution of the inference processing completes. For example, as shown in FIG. 4, when execution of the inference phase 412 completes at time t₃, the last prediction resulting from the inference phase 412 is provided, as an initial condition, back to a third portion of the physics-based simulation 414.

Then as shown in FIG. 4, the method 300 reverts back to block 302 and the next portion of the physics-based simulation (e.g., the third portion of the physics-based simulation 414 in this example), from time t₃ to time t₄, based on the initial condition provided to the third portion of the physics-based simulation 414 resulting from the inference phase 412. In the example shown in FIG. 4, the third portion of the physics-based simulation 414 is also performed for 500 steps.

During execution of the third portion of the physics-based simulation 414, corrections are made, by the third portion of the physics-based simulation 414, to any incorrect predictions resulting from the inference phase 412.

A determination is again made (e.g., by APD 116), at decision block 304, as to whether there are any additional portions of the physics-based simulation or any additional training to perform. For example, after performing the third portion of the physics-based simulation 414, in response to there not being any additional portions of the physics-based simulation and there not being any additional training of a neural network to be performed (No decision), the method ends at block 306.

Although not illustrated in FIG. 4, in some cases, new simulation data can be generated to retrain the neural network model 408 and to improve the accuracy of the predictions made by the neural network model 408. For example, after the third portion of the physics-based simulation 414 is performed at block 302, in response to additional training of a neural network model 408 being determined at decision block 304, the data that was generated during the third portion of the physics-based simulation 414 can be used to retrain the neural network model 408 at block 308.

Alternatively, a new neural network model can be trained from scratch (i.e., without the data generated during the third portion of the physics-based simulation 414). For example, a new model is determined (e.g., by APD 116) to be retrained in response to an amount of change in the simulated physical behavior of the system being greater than a change threshold such that the previously trained model should not be used. Alternatively, the previously trained neural network model is preserved and used as an initial estimation in a new training phase based on new data.

After the neural network model is retrained using the data that was generated during the third portion of the physics-based simulation 414 (or a new neural network model is trained from scratch), inference processing is performed at block 310, and a prediction is provided back to the physics-based simulation (e.g., as an input to the third portion of the physics-based simulation 414) and method then once again reverts back to block 302 to re-execute the last third portion of the physics-based simulation.

After the physics-based simulation is completed, at block, 306, one or more predictions are determined (e.g., by APD 116) regarding the physical processes (e.g., predictions for designing a new machine, predictions for designing new materials or predictions for making societal decisions).

As illustrated in FIG. 4, the physics-based simulation is performed in less time (i.e., as illustrated by the time gain between time t₄ and time t₅) using the machine learning neural network model 408 training and inference phase 412 (i.e., the hybrid workflow 404) than performing the physics-based simulation without using any neural network training and inference processing (i.e., the baseline workflow 402).

It should be understood that many variations are possible based on the disclosure herein. Although features and elements are described above in particular combinations, each feature or element can be used alone without the other features and elements or in various combinations with or without other features and elements.

The methods provided can be implemented in a general purpose computer, a processor, or a processor core. Suitable processors include, by way of example, a general purpose processor, a special purpose processor, a conventional processor, a digital signal processor (DSP), a plurality of microprocessors, one or more microprocessors in association with a DSP core, a controller, a microcontroller, Application Specific Integrated Circuits (ASICs), Field Programmable Gate Arrays (FPGAs) circuits, any other type of integrated circuit (IC), and/or a state machine. Such processors can be manufactured by configuring a manufacturing process using the results of processed hardware description language (HDL) instructions and other intermediary data including netlists (such instructions capable of being stored on a computer readable media). The results of such processing can be maskworks that are then used in a semiconductor manufacturing process to manufacture a processor which implements features of the disclosure.

The methods or flow charts provided herein can be implemented in a computer program, software, or firmware incorporated in a non-transitory computer-readable storage medium for execution by a general purpose computer or a processor. Examples of non-transitory computer-readable storage mediums include a read only memory (ROM), a random access memory (RAM), a register, cache memory, semiconductor memory devices, magnetic media such as internal hard disks and removable disks, magneto-optical media, and optical media such as CD-ROM disks, and digital versatile disks (DVDs).

What is claimed is:

1. A processing device comprising:
memory; and
a processor configured to perform a physics-based simulation by:
executing a portion of the physics-based simulation;
training a neural network model based on results from executing the portion of the physics-based simulation;
performing inference processing based on results of the training of the neural network model; and
providing a prediction, based on the inference processing, as an input back to the physics-based simulation.

2. The processing device of claim 1, wherein the processor is configured to provide the prediction as the input to a next portion of the physics-based simulation.

3. The processing device of claim 1, wherein the processor is configured to train the neural network model, based on the results from executing the portion of the physics-based simulation, in response to at least one of:
an additional portion of the physics-based simulation determined to be executed; and
additional training of a neural network determined to be performed.

4. The processing device of claim 3, wherein in response to additional training of the neural network model being determined, the processor is configured to retrain the neural network model using data generated during the portion of the physics-based simulation.

5. The processing device of claim 3, wherein in response to additional training of a neural network model being determined, the processor is configured to train a new neural network model without data generated during the portion of the physics-based simulation.

6. The processing device of claim 1, wherein the physics-based simulation and the inference processing are performed for a same number of steps.

7. The processing device of claim 6, wherein the same number of steps is performed by the inference processing in less time than the portion of the physics-based simulation.

8. The processing device of claim 1, wherein the processor is configured to store part of the results from executing the portion of the physics-based simulation in the memory, the part of the results comprising at least one of:
a subsample of the simulated results in space and time; and
a portion of state variables.

9. A method of performing a physics-based simulation comprising:
executing a portion of the physics-based simulation;
training a neural network model based on results from executing the portion of the physics-based simulation;
performing inference processing based on results of the training of the neural network model; and
providing a prediction, based on the inference processing, as an input back to the physics-based simulation.

10. The method of claim 9, further comprising providing the prediction as the input to a next portion of the physics-based simulation.

11. The method of claim 9, further comprising training the neural network model, based on the results from executing the portion of the physics-based simulation, in response to at least one of:
an additional portion of the physics-based simulation determined to be executed; and
additional training of a neural network determined to be performed.

12. The method of claim 11, further comprising, in response to additional training of a neural network model being determined, retraining the neural network model using data generated during the portion of the physics-based simulation.

13. The method of claim 11, further comprising, in response to additional training of a neural network model being determined, training a new neural network model without data generated during the portion of the physics-based simulation.

14. The method of claim 13, further comprising training the new neural network model in response to an amount of change in simulated physical behavior being greater than a physical behavior change threshold.

15. The method of claim 9, wherein the portion of the physics-based simulation and the inference processing are performed for a same number of steps.

16. The method of claim 15, wherein the same number of steps is performed by the inference processing in less time than the portion of the physics-based simulation.

17. The method of claim 9, further comprising storing a part of the results from executing the portion of the physics-based simulation, the part of the results comprising at least one of:
a subsample of the simulated results in space and time; and
a portion of state variables.

18. A method of performing a physics-based simulation comprising:
executing a first portion of the physics-based simulation;
training a neural network based on results of the first portion of the physics-based simulation to generate a trained neural network model;
executing a second portion of the physics-based simulation during a period of time in which the neural network model is trained;
performing inference processing based on results of the trained neural network model; and
providing a prediction of the inference processing to a third portion of the physics-based simulation when execution of the inference processing completes,
wherein one or more predictions, regarding physical processes, are generated from results of the physics-based simulation.

19. The method of claim 18, further comprising providing data, generated by the second portion of the physics-based simulation, to the neural network model while the second portion of the physics-based simulation is executing.

20. The method of claim 18, further comprising using data, generated by the second portion of the physics-based simulation, to validate the trained neural network model after the training of the neural network model is complete.
